(19) United States
(12) Patent Application Publication
(10) Pub. No.: US 2006/0205182 A1
(43) Pub. Date: Sep. 14, 2006

(54) Method for manufacturing semiconductor device

(75) Inventor: Koji Soejima, Kanagawa (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KANAGAWA (JP)

(21) Appl. No.: 11/364,070

(22) Filed: Mar. 1, 2006

(30) Foreign Application Priority Data
Mar. 10, 2005 (JP) 2005-067626

(51) Int. Cl. H01L 21/00

(52) U.S. Cl. 438/460

(57) ABSTRACT

A method of dicing a semiconductor wafer includes providing an interconnect layer providing a protective film on the interconnect layer on the side of a device-forming surface of a silicon wafer, irradiating the protective film with a laser beam to provide a trenched portion that extends through the interconnect layer from the protective film and reaches to an inside of the silicon wafer, removing a portion of the silicon wafer selectively in a depth direction from a bottom of the trenched portion, after irradiating with the laser beam to provide the trenched portion and dividing the silicon wafer along the portion where the trenched portion is provided into respective pieces of the silicon wafer, after removing a portion of the silicon wafer 101 selectively in the depth direction.

This application is based on Japanese patent application No. 2005-067,626, the content of which is incorporated hereinto by reference.

### BACKGROUND

1. Technical Field

The present invention relates to a method for manufacturing a semiconductor device, and particularly relates to method for isolating a plurality of semiconductor devices formed thereon into individual devices.

2. Related Art

A dicing process and an etch process have conventionally been employed as processes for dividing a plurality of semiconductor devices formed on a wafer into individual devices. Such type of technology is described in Japanese Patent Laid-Open No. 2003-179,005 and Japanese Patent Laid-Open No. 2004-55,684.

In the method disclosed in Japanese Patent Laid-Open No. 2003-179,005, a half-cut-off is first formed by etching a dicing line from a side of a surface of a wafer having an electronic circuit formed thereon. A back grinding tape is adhered onto a front surface of the wafer, and a back surface of the wafer is partially polished to reduce a predetermined thickness, leaving a portion thereof, so as to avoid forming a communication with the half-cut-off. Then, an etch process or a chemical mechanical polishing (CMP) process is conducted from the back surface of the wafer to divide the wafer into individual semiconductor devices. According to the method described in Japanese Patent Laid-Open No. 2003-179,005, it is possible to effectively remove cracks that have been created in the wafer in the back polishing process, to improve the reliability of the device after the mounting process is completed.

On the contrary, in a method described in Japanese Patent Laid-Open No. 2004-55,684, a semiconductor substrate having a protective film, which has a protective film adhered onto a surface, on which respective device-forming regions to be divided are defined, is fixed and retained to a jig, and a metal layer is formed on the entire exposed surface of the semiconductor substrate having the protective film, and then, portions of the metal layer that correspond to boundary portions dividing the respective device-forming regions are removed via a laser processing, and further, the semiconductor substrate is divided along the removed portion of the metal layer into respective semiconductor devices via a plasma etch process or the like. According to the process described in Japanese Patent Laid-Open No. 2004-55,684, it is described that a handling of a thinned semiconductor substrate can be easily conducted and a dicing process for the semiconductor substrate can be conducted in shorter time.

### SUMMARY OF THE INVENTION

However, the present inventor has investigated the processes described in Japanese Patent Laid-Open No. 2003-179,005 and Japanese Patent Laid-Open No. 2004-55,684, and found that there is a room for improvements described as follows.

First of all, the technology described in Japanese Patent Laid-Open No. 2003-179,005 involves removing silicon from the device-forming surface of the wafer via the etch process. Therefore, when an oxide film or an interconnect is provided in a region to be removed via a dicing on a device formation surface (circuit surface) on the wafer, a complicated process step for removing materials except silicon conducted with the etch process for the wafer is required. On the other hand, when a plurality of semiconductor devices are required to be connected via interconnects, for example, the interconnects are still remained in regions to be broken in the dicing process. In such case, when a dicing process is conducted to divide the wafer into a plurality of semiconductor chips, it is required to ensure breaking the remaining interconnects and to prevent the chip from causing a short circuit by a broken interconnect. However, when a silicon oxide film or an interconnect are in the dicing region, it is difficult to additionally remove the silicon oxide film or the interconnects in the process for etching the wafer.

Similarly, in Japanese Patent Laid-Open No. 2004-55,684, a metal layer is formed in a back surface of a silicon wafer, and a trimming process is conducted with a laser beam from the back surface thereof, and thereafter, the silicon wafer is divided into individual chip units via an dry etch process. Although a laser beam is employed to conduct a trimming of the metal layer that is formed on the back surface of the silicon wafer, a plasma etch process is still included for etching the silicon oxide film and the interconnect in vicinity of the device-forming surface of the silicon wafer. Therefore, the aforementioned problem of “when a silicon oxide film or an interconnect are in the dicing region, it is difficult to additionally remove the silicon oxide film or the interconnects in the process for etching the wafer” existing in the technology described in Japanese Patent Laid-Open No. 2003-179,005 has not been solved.

According to one aspect of the present invention, there is provided a method for manufacturing a semiconductor device, comprising: providing an interconnect layer on a device-forming surface of a semiconductor substrate; providing a protective film on the interconnect layer; irradiating the protective film with a laser beam to provide a trenched portion that extends from the protective film through the interconnect layer and reaches to an inside of the semiconductor substrate; removing a portion of the semiconductor substrate selectively in depth direction from a bottom of the trenched portion, after the providing the trenched portion; and dividing the semiconductor substrate along the portion where the trenched portion is provided into respective pieces of the semiconductor substrate, after the removing a portion of the semiconductor substrate selectively in depth direction.

According to the method, the protective film is provided on the device-forming surface, and the protective film is irradiated with a laser beam to form the trenched portion. Consequently, the trenched portion can be stably provided in a certain location. In addition, the irradiation of the protective film with the laser beam allows conducting a dicing process while providing a protection to the surface of the semiconductor substrate. Further, when an interposing layer is presented between the semiconductor substrate and the protective film, the trenched portion extending through the interposing layer can be simply and surely provided by irradiating with a laser beam to provide a trenched portion extending to the inside of the semiconductor substrate. Further, since the irradiation with the laser beam is employed for forming the trenched portion, width of the formed trenched portion can be reduced, as compared with the conventional dicing process that employs a dicing saw. Moreover, since portions of the semiconductor substrate are removed selectively in depth direction after it is irradiated with a laser beam to provide the trenched portion that extends to the inside of the semiconductor substrate, rate of the processing for providing the trenched portion can be improved, while the reduced width of the trenched portion is ensured.

As such, according to the method of the present invention, the processing width in the dicing process can be reduced, while providing the protection to the device-forming surface of the semiconductor substrate. Thus, degree of integration in the device-forming region provided in one piece of the semiconductor substrate can be enhanced, and a production yield for producing the semiconductor device by dicing the semiconductor substrate along the periphery of the device-forming region can be improved.

It is to be understood that the invention is capable of use in various other combinations, modifications, and environments, and any other exchange of the expression between the method and device or the like according to the present invention may be effective as an alternative of an embodiment according to the present invention.

For example, according to the present invention, a semiconductor device obtained by the above-described method for manufacturing the semiconductor device can be presented.

As described above, according to the present invention, the processing width of the dicing process for the semiconductor wafer can be reduced by providing the protective film on the device-forming surface, irradiating the protective film with a laser beam to provide a trenched portion extending in the inside of the semiconductor substrate from the protective film, and thereafter, selectively removing the semiconductor substrate from a bottom of the trenched portion in depth direction, and dividing the semiconductor substrate along portions where the trenched portion is provided into respective pieces of the semiconductor substrate.

### BRIEF DESCRIPTION OF THE DRAWINGS

The above and other objects, advantages and features of the present invention will be more apparent from the following description taken in conjunction with the accompanying drawings, in which:

FIG. 1A to FIG. 1C are cross-sectional views of a semiconductor device according to the present invention, illustrating a process for manufacturing the semiconductor device in first embodiment;

FIG. 2 A and FIG. 2B are cross-sectional views of the semiconductor device, illustrating the process for manufacturing the semiconductor device in first embodiment;

FIG. 3 is a plan view of a silicon wafer, useful in illustrating a process for manufacturing the semiconductor device in first embodiment;

FIG. 4 is a cross-sectional view, illustrating configuration of the semiconductor device in first embodiment;

FIG. 5 is a perspective view of the semiconductor device of FIG. 4, enlarging the geometry of the corner portion;

FIG. 6 is a cross-sectional view of the semiconductor device of FIG. 4, enlarging the geometry of the dicing surface;

FIG. 7A to FIG. 7C are cross-sectional views of a semiconductor device according to the present invention, illustrating a process for manufacturing the semiconductor device in second embodiment;

FIG. 8A to FIG. 8C are cross-sectional views of a semiconductor device, illustrating the process for manufacturing the semiconductor device in second embodiment;

FIG. 9 is a cross-sectional view of a semiconductor device according to the present invention, illustrating a configuration of the semiconductor device in third embodiment;

FIG. 10A to FIG. 10C are cross-sectional view of a semiconductor device according to the present invention, illustrating a configuration of the semiconductor device in fourth embodiment; and

FIG. 11 cross-sectional view of the semiconductor device, illustrating the process for manufacturing the semiconductor device in fourth embodiment.

### DETAILED DESCRIPTION

The invention will be now described herein with reference to illustrative embodiments. Those skilled in the art will recognize that many alternative embodiments can be accomplished using the teachings of the present invention and that the invention is not limited to the embodiments illustrated for explanatory purposed.

Preferred embodiments according to the present invention will be described as follows in reference to the annexed figures.

In all figures, identical numeral is assigned to an element commonly appeared in the figures, and the detailed description thereof is not presented in the following descriptions. In addition, in the following embodiments, the side of the device-forming surface of the silicon wafer or the silicon substrate is defined as “top”, “front” or “principal”, and the surface (back surface) opposite to the device-forming surface is defined as “bottom” or “back”.

### First Embodiment

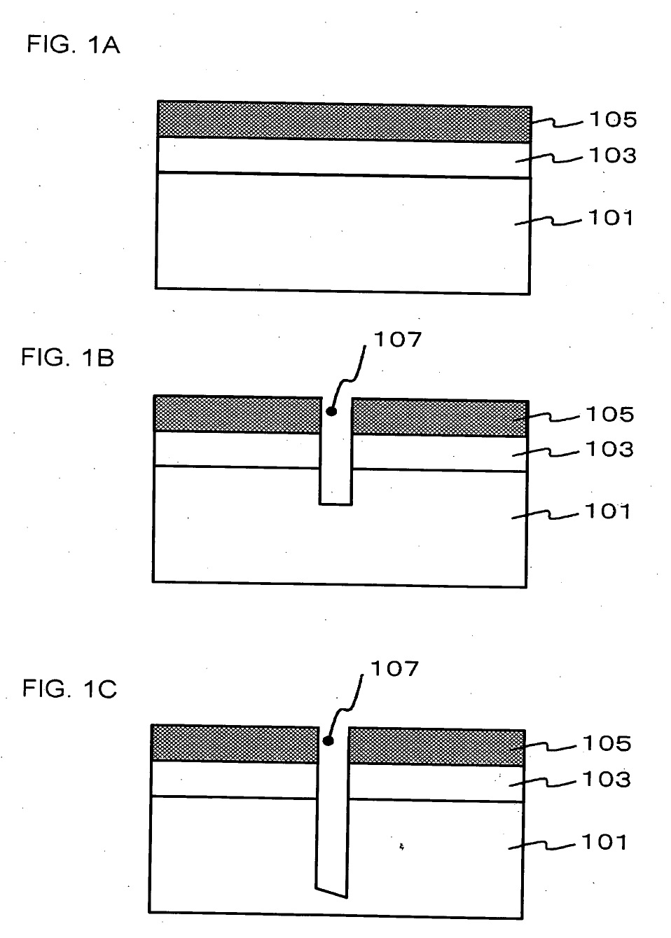

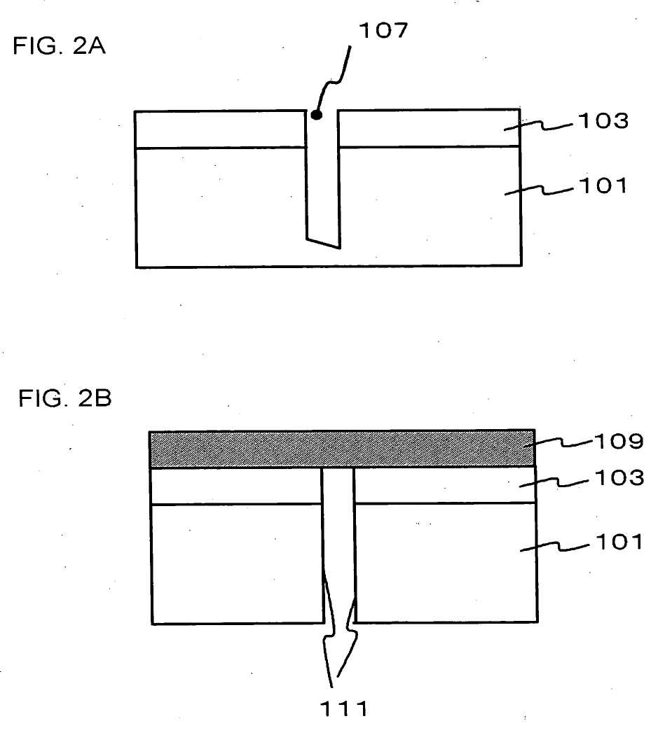

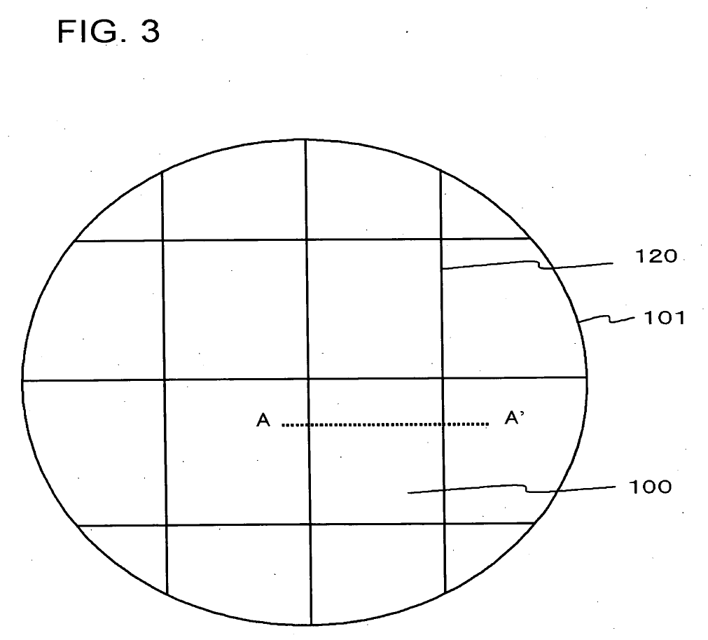

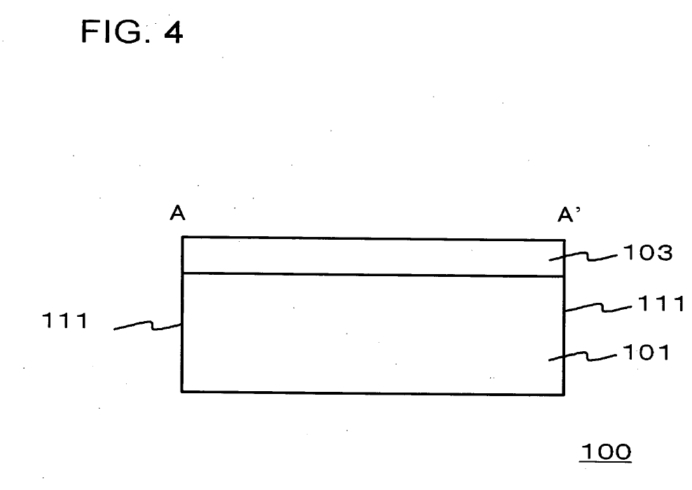

FIG. 1A to FIG. 1C, FIG. 2A and FIG. 2B are cross-sectional views, illustrating a process for manufacturing a semiconductor device of the present embodiment. FIG. 3 is a plan view, illustrating a configuration of the semiconductor wafer in a status of preliminary step to the status of FIG. 1A. FIG. 4 is a cross-sectional view illustrating a configuration of the semiconductor device obtained by procedures shown in FIG. 3, FIG. 1A to FIG. 1C, FIG. 2A and FIG. 2B. FIG. 4 represents the view corresponds to a cross-section along line A-A′ of FIG. 3.

First of all, the configuration of the semiconductor device according to the present embodiment will be described in reference to FIG. 3 and FIG. 4. A semiconductor device 100 shown in FIG. 3 and FIG. 4 is configured that a silicon wafer 101 is divided by dicing along dicing lines 120, and an interconnect layer 103 is provided on each of the divided silicon wafer 101. The interconnect layer 103 includes an insulating film (not shown) and an interconnect composed of a conductive material (not shown) buried in the insulating film. The interconnect may be composed of a metal such as, for example, copper and the like. In addition, the interconnect layer 103 may have a multiple-layered structure including an interconnect layer and an insulating interlayer that are stacked.

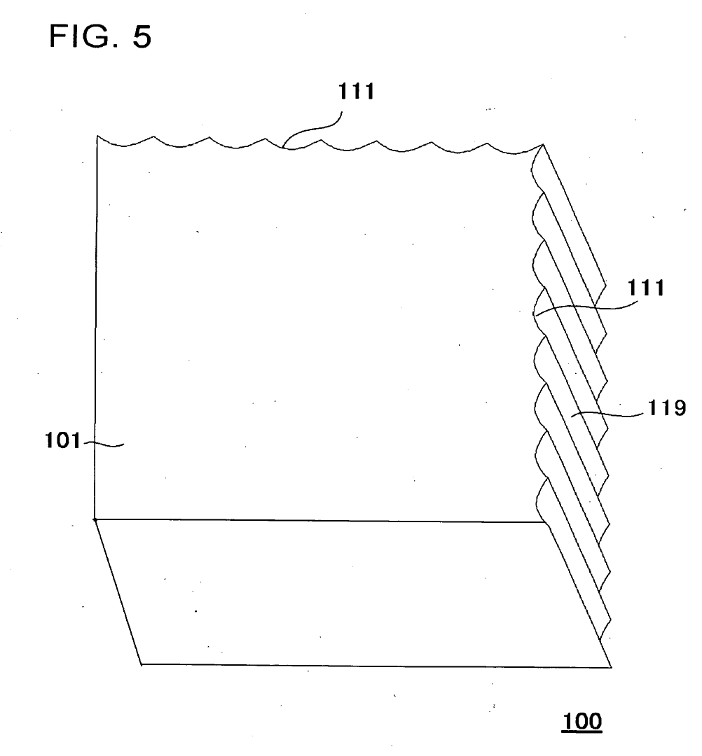

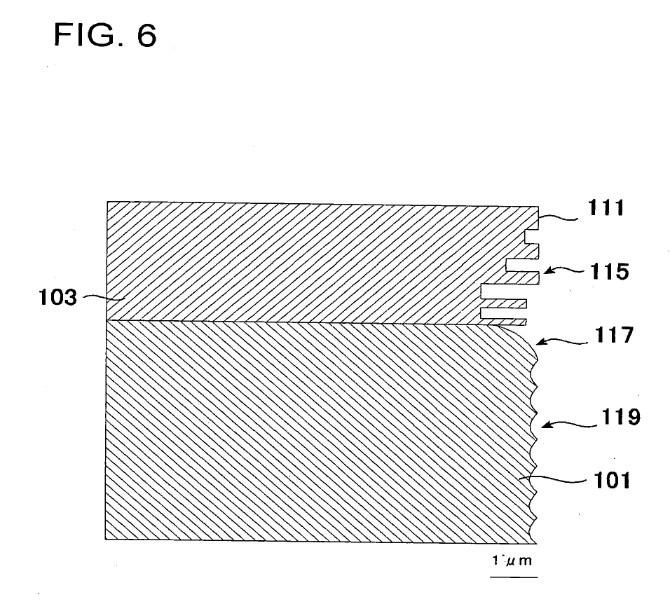

Here, a side surface of the semiconductor device 100, or namely a dicing surface 111 has a cross-sectional geometry that is specific to a manufacturing process as described later, and this feature will be described in reference to FIG. 5 and FIG. 6 after the description of the process for manufacturing the semiconductor device 100.

Next, the method for manufacturing the semiconductor device 100 will be described in reference to FIG. 1A to FIG. 1C, FIG. 2A, FIG. 2B and FIG. 3. The semiconductor device 100 is obtained by the following process operations:

Step 105: providing the interconnect layer 103 on a device-forming surface of the semiconductor substrate (silicon wafer 101);

Step 101: providing a protective film 105 on the interconnect layer 103;

Step 102: irradiating the protective film 105 with a laser beam to provide a trenched portion 107 that extends through the interconnect layer 103 from the protective film 105 and reaches to an inside of the silicon wafer 10′;

Step 103: removing a portion of the silicon wafer 101 selectively in depth direction from a bottom of the trenched portion 107, after the step for irradiating with the laser beam to provide the trenched portion 107; and

Step 104: dividing the silicon wafer 101 along the portion where the trenched portion 107 is provided into respective pieces of the silicon wafer 101, after the step 103 of removing a portion of the silicon wafer 101 selectively in depth direction.

In step 102, the silicon wafer 101 is irradiated with a laser beam from a side of a device-forming surface or namely a side of the surface for forming the protective film 105.

The operation of removing the silicon wafer 101 selectively in depth direction in step 103 includes an operation of partially removing the silicon wafer 101 via an etch process.

The operation of dividing the silicon wafer into respective pieces thereof in step 104 includes an operation of reducing the thickness of silicon wafer 101 from a back surface thereof.

The operation of providing the interconnect layer in step 105 includes an operation of providing an interconnect in the region, which is irradiated with a laser beam, in the interconnect layer 103. In this case, the operation of irradiating with the laser beam to provide the trenched portion in step 102 may correspond to an operation of providing the trenched portion 107 that extends from the protective film 105 via the interconnect layer 103 to an inside of the silicon wafer 101 and breaking the interconnect.

The protective film 105 is composed of a nonmetallic material.

A method for manufacturing of the present embodiment includes an operation of removing the protective film 105 (step 106) after the operation of removing the silicon wafer 101 selectively in depth direction in step 103. In the present embodiment, the protective film 105 is removed before the operation of diving the wafer into respective pieces instep 104.

The protective film 105 may be a film containing a water-soluble resin, and the operation of removing the protective film 105 in step 106 may comprise an operation of removing the protective film 105 by cleaning the device-forming surface with water.

In addition, the protective film 105 may be a film that contains an organic solvent-soluble resin, and the operation of removing the protective film 105 in step 106 may comprise an operation of removing the protective film 105 by cleaning the device-forming surface with an organic solvent.

Respective operations will be described in detail.

First of all, as shown in FIG. 3, a large scale integrated circuit (LSI) including a certain device, a certain diffusion layer and a certain interconnect layer 103 is formed on a device-forming surface of the silicon wafer 101. Although the thickness of the non-processed silicon wafer 101 is not particularly limited, a typical thickness may be, for example, about 500 to 800 μm. Then, the protective film 105 is provided over the entire surface of the device-forming surface of the silicon wafer 101 having the LSIs formed thereon (FIG. 1A). The protective film 105 functions as a pad contamination-preventing film for the LSI.

Subsequently, an irradiation with a laser beam is conducted along dicing lines 120 (FIG. 3) on the device-forming surface of the silicon wafer 101 having the protective film 105 provided thereon to form the trenched portion 107. In this occasion, the silicon wafer 101, the interconnect layer 103 and the protective film 105 in the region for forming the trenched portion 107 are partially removed. The trenched portion 107 extends through the protective film 105 and the interconnect layer 103, and reaches to the inside of the silicon wafer 101.

Next, the removal of the portion of the silicon wafer 101 is further proceeded toward the depth direction from the bottom of the trenched portion 107 (FIG. 1C). In this case, the silicon wafer 101 is anisotropically etched in the depth direction from an exposed portion of the silicon wafer 101 in the trenched portion 107 by employing a dry etch process.

Then, after removing the protective film (FIG. 2A), an adhesive tape 109 is adhered onto the entire device-forming surface of the silicon wafer 101. For example, a known dicing tape may be employed for the adhesive tape 109. Subsequently, the silicon wafer 101 is polished from the back surface by employing a mechanical polishing process or the like to reduce the thickness thereof (FIG. 2B). The thickness of the thinned silicon wafer 101 by the polishing operation may be, for example, on the order of several-tens to 100 μm. This process for reducing the thickness of the wafer allows the trenched portion 107 extending through the silicon wafer 101. Thereafter, the adhesive tape 109 is stripped to provide divided pieces of the silicon wafer 101, thereby obtaining a plurality of semiconductor devices 100.

The protective film 105 may be composed of a material, which is capable of providing a protection to the upper surface of the interconnect layer 103 during the irradiation with the laser beam in step 102 and during the etching in step 103, and may also be preferably composed of a material, which can be relatively easily stripped in step 106 and provides no emission of contamination to the interconnect layer 103 and the silicon wafer 101 in such stripping operation.

More specifically, a nonmetallic material may be employed for the material of the protective film 105. Having such configuration, it is not necessary to employ an acid or a base as a stripping solution for stripping the protective film, so that a contamination to the silicon wafer and/or the interconnect layer and a damage thereto can be prevented. The available nonmetallic materials typically includes, for example, resin materials such as organic resin materials and the like.

The available resin materials typically includes, for example: water-soluble resins such as polyvinyl alcohol (PVA) and the like; organic solvent-soluble (organic solvent-containing) resins such as novolac resins, acrylic resins and the like; and sublimable resin materials that is capable of sublimating or vaporizing at a temperature of not lower than a predetermined temperature of, for example, equal to or higher than 60 degree C. Among these, a typical sublimable resin material may be, more specifically, commercially available from Nippon Soda Co., Ltd., Tokyo Japan, under a trade name of “PSD series”.

In addition, in step 101, a method for applying of the protective film 105 may be suitably selected according to the material of the protective film 105, and the typical methods include, for example, spin coating, curtain coating, dipping, spraying or the like.

The thickness of the protective film 105 may be suitably selected according to a combination of the material of the protective film 105 and the material of the silicon wafer 101, or namely according to an etching selectivity of the protective film 105 with silicon in dry etch process in step 103.

For example, when the above-listed PVA is employed, the thickness of the protective film 105 may be, for example, equal to or larger than 3 μm. Having such configuration, the protection of the interconnect layer 103 can be ensured during an anisotropic etching for the silicon wafer 101 in step 103. In addition, the thickness of the protective film 105 may be, for example, equal to or lower than 50 μm. Having such configuration, the stripping of the protective film 105 can be further facilitated in step 106.

When the above-listed organic solvent-soluble resin is employed, the thickness of the protective film 105 may be, for example, equal to or larger than 3 μm. Having such configuration, the protection of the interconnect layer 103 can be ensured during an anisotropic etching for the silicon wafer 101 in step 103. In addition, the thickness of the protective film 105 may be, for example, equal to or lower than 10 μm. Having such configuration, the stripping of the protective film 105 can be further facilitated in step 106.

Laser beam available for the laser beam processing in step 102 may utilize, for example, second-harmonic generation (SHG) or third-harmonic generation (THG) of yttrium aluminum garnet (YAG) laser beam. Alternatively, an excimer laser such as ArF excimer laser may be employed.

In dry etch process for the silicon wafer 101 in step 103, for example, Bosch process, a dry etch process employing an etchant gas containing boron (B), a cryo-process or the like may be employed. Bosch process is an anisotropic etch process, which comprises repetitions of a combination of a formation of the protective film by exposing to a CF-containing atmosphere and an etching for the silicon wafer by employed a F-containing gas. More specifically, a simultaneous exposure to SF₆ and O₂ and an exposure to C₄F₈ are alternately conducted to carry out an etch process. The cryo-process described herein is an etch process for etching the silicon wafer 101 employing an etchant gas such as SF₆ gas and the like in a condition that the silicon wafer is cooled to a temperature of equal to or lower than −50 degree C., for example. Geometry of the dicing surface 111 of the semiconductor device 100 is specific to the etching process as discussed later in reference to FIG. 5 and FIG. 6.

The process for stripping the protective film 105 in step 106 may be suitably selected according to the material of the protective film 105. For example, when a water soluble resin is employed for the material of the protective film 105, the protective film 105 can be stripped by rinsing the device-forming surface of the silicon wafer 101 with water. On the other hand, when an organic solvent-soluble material is employed for the material of the protective film 105, the device-forming surface of the silicon wafer 101 can be cleaned by employing a solvent that is capable of dissolving the protective film 105. When the material of protective film 105 is a sublimable material, the process for sublimating the material by heating the silicon wafer 101 at a temperature equal to or higher than a predetermined temperature, for example at a temperature equal to or higher than 60 degree C. can be employed. Alternatively, a stripping by exposing to an oxygen plasma (ashing) a peeling off by employing an adhesive tape may be employed according to the material of the protective film 105.

When the processes except the cleaning processes employing solvents such as water or an organic solvent are employed among the process for stripping the protective film 105 described above, an additional cleaning process by employing a solvent may further be conducted. This can provide the further ensured removal of contaminants that have been adhered onto the protective film 105 in the laser beam processing in step 101, so that contamination of the interconnect layer 103 and the silicon wafer 101 can be more surely inhibited.

Next, the configuration of the semiconductor device 100 obtained by the above-mentioned manufacturing process will be described. Since the semiconductor device 100 is obtained by the above-mentioned manufacturing process, the device has a cross-sectional geometry that reflects the manufacturing process steps. Here, a cross-sectional geometry of the semiconductor device 100 will be described by illustrating a case of employing Bosch process in the dry etching for the silicon wafer 101 in step 103, in reference to FIG. 5 and FIG. 6. When Bosch process is employed, the geometry of the dicing surface 111 of the obtained semiconductor device 100 is a combination of corrugated portions in the interconnect layer 103, retracted portions in vicinity of an interface with the interconnect layer 103 created by the side etch of the silicon wafer 101 and periodical corrugated portions of the silicon wafer 101 created by Bosch process. In the silicon wafer 101, a hangnail-like protruding portion or a crack, which typically appears when a dicing saw is employed to cut thereof, is not created.

FIG. 5 is a perspective view, enlarging a geometry of a corner of the semiconductor device 100. In FIG. 5, a geometry of the corner of the semiconductor device 100, at which two dicing surfaces 111 intersects, is illustrated. Here, in FIG. 5, the interconnect layer 103 on the silicon wafer 101 is not shown. As shown in FIG. 5, when Bosch process is employed, a periodical corrugated surface 119 having a width (interval) of about 2 to 10 μm along a direction of a principal surface of the silicon wafer 101 is formed on the dicing surface 111. Further, as described in the following in reference to FIG. 6, a plurality of concave surfaces having shorter intervals are formed in a concave surface composing the corrugated surface 119.

FIG. 6 is a cross-sectional view, enlarging a vicinity of the interconnect layer 103 in the dicing surface 111 of the semiconductor device 100 shown in FIG. 4. As shown in FIG. 6, the interconnect layer 103 has a multiple-layered structure including an interconnect layer and an insulating interlayer that are stacked. In the dicing surface 111 of FIG. 6, the side surface portion of the interconnect layer 103 is formed by being cut-off by employing a laser beam in step 102. Consequently, in the case of the configuration of the interconnect layer 103 that has a multiple-layered structure of different materials, the dicing surface 111 is heated in the process of the irradiation with the laser beam, so that pulse-shaped corrugated surface 115, which reflects different melting points of the respective materials composing the interconnect layer 103, appears in the dicing surface 111.

The corrugated surface 115 has the geometry that reflects durability for heating of respective layers of the interconnect layer 103. It is considered that the corrugated surface 115 is created due to different levels of the retractions of the retracted portions along a direction from the edge of the dicing surface 111 toward the inside of the surface, corresponding to the different melting points of the composing materials. For example, when a silicon oxide film, a low dielectric constant insulating interlayer and a nitride film that functions as an etch stop film are stacked in a predetermined order, a corrugated surface that reflects the melting points of these films can be formed. In addition, for example, a low dielectric constant insulating interlayer, a metallic interconnect and an SiO₂ film are stacked in a predetermined location in a predetermined sequence along the dicing line 120 in the interconnect layer 103, rate of the removal at the edges to form a retracted portions is the largest in the low dielectric constant insulating interlayer, the second largest in the metallic interconnect, and the smallest in the SiO₂ film.

As shown in FIG. 6, a trench-shaped pattern is formed in the upper portion of the silicon wafer 101 by a laser beam in step 102. Consequently, the silicon wafer 101 in vicinity of the boundary with the interconnect layer 103 melts via an irradiation with a laser beam and the melted materials are scattered to cause a side-etching, thereby creating the retracted portion 117. In addition, since the dicing surface 111 is a surface formed via Bosch process in regions except the regions to be processed by the irradiation with the laser beam in the silicon wafer 101, concaves and convexes are periodically formed with an interval (pitch) of, for example, about 1 μm along normal direction to the silicon wafer 101 in the corrugated surface 119. The concave portions composing this corrugated portion elongates along a direction of the surface of the silicon wafer 101.

As shown in FIG. 5 and FIG. 6, the corrugated surface 119 has a structure, in which concave and convex with larger intervals are formed and further concave and convex with smaller intervals are formed in the concave portion of the concave and convex with larger interval so as to be orthogonal to the concave and convex with large intervals. The concave and convex with larger intervals are provided along a direction in the principal surface of the silicon wafer 101, as shown in FIG. 5, and the concave portions elongate in normal direction to the silicon wafer 101. In addition, the concave and convex with smaller intervals are provided along the normal direction to the silicon wafer 101, as shown in FIG. 6, and the concave portions elongate in the direction in the principal surface of the silicon wafer 101.

Alternatively, when a cryo-process or a dry etch process using an etchant gas containing B is employed in stead of Bosch process in step 103, the cut surface of the silicon wafer 101 is a flat and smooth surface, and thus periodical concave and convex surfaces 119 are not formed. On the other hand, the region to be removed by the irradiation with the laser beam, or in other words upper regions of the interconnect layer 103 and the silicon wafer 101 have a cross-sectional geometry including a corrugated surface 115 and a retracted portion 117, similarly as in the case shown in FIG. 6.

Next, advantageous effects obtainable by employing the semiconductor device 100 will be described. In the manufacturing process for the semiconductor device 100, the protective film 105 is formed on the LSI surface provided on the device-forming surface of the silicon wafer 101, and the surface of the silicon wafer 101 is exposed by processing with a laser beam, and a dry etch process is conducted to divide the wafer into individual pieces. Then, this etch process is stopped on the way of removing a certain thickness of the silicon wafer 101, and then, a polishing the wafer is conducted from the back surface thereof to complete the process for dividing the wafer into respective pieces. Consequently, the following advantageous effects can be obtained.

First of all, the semiconductor device 100 is configured to have a portion that is removed from the side of the formation surface of the interconnect layer 103 to an inside of the silicon wafer 101 via the irradiation with the laser beam. Consequently, the configuration can reduce the processing width in the dicing process, as compared with the semiconductor device obtained by a conventional process. Consequently, the process is configured that multiple semiconductor devices 100 can be obtained from one piece of the silicon wafer 101.

For example, in a case of a conventional semiconductor device, which is obtained by dicing the silicon wafer 101 employing a dicing saw, a dicing width of, for example, about 30 μm is required for the dicing process with the dicing saw, and further, an allowance of about 20 μm may be required for each side of the dicing line. Consequently, a width of the dicing region of, for example, about 70 μm is required for the silicon wafer 101 that presents a plurality of semiconductor devices 100.

On the contrary, since an irradiation with a laser beam is conducted in step 102 in the present embodiment, the width of the trenched portion 107 formed on the dicing line 120 can be reduced, and cracks to be generated in the dicing surface in the case of employing the dicing saw can be inhibited, so that a dimension of an allowance provided in each side of the trenched portion 107 can be reduced. More specifically, a laser beam-processing width may be reduced to, for example, about 10 μm for wave length of 0.5 μm, and about 5 μm for wave length of 0.3 μm. Consequently, when the dicing width of, for example, 10 μm is provided and a width allowance of 5 μm is provided in each side thereof, the width of the dicing region on the silicon wafer 101 can be reduced to about 20 μm. Consequently, the process is configured that multiple semiconductor devices 100 can be obtained from one piece of the silicon wafer 101, and that the configuration is suitable for reducing the manufacture cost.

In addition, when an interposed layer, and more specifically the interconnect layer 103 is provided on the dicing line 120 between the silicon wafer 101 and the protective film 105, the interconnect or the insulating interlayer in the interconnect layer 103 can be surely and stably diced by irradiating with a laser beam from the side of the device-forming surface of the silicon wafer 101. Since the insulating film composing the interconnect layer 103 is partially removed with a laser beam, it is not necessary to conduct multiple etch processes in different etching conditions that are dedicated for the insulating film composing the interconnect layer 103 and the silicon wafer 101, as in the case of Japanese Patent Laid-Open No. 2003-179,005. Consequently, among the process operations for manufacturing the semiconductor device 100, the operation for diving the silicon wafer 101 into individual pieces can be simplified, so that the process is configured that the manufacturing cost can be further reduced.

In addition, since the process disclosed in Japanese Patent Laid-Open No. 2003-179,005 described in the section of the background of the invention involves etching the silicon wafer from the device-forming surface, the width of the dicing line 120 is broaden, as compared with the present embodiment that involves forming the trenched portion 107 by an irradiation with a laser beam in advance. Further, as described above, there is a concern that the manufacturing process operation for removing materials except silicon via an etch process could be complicated. More specifically, when a film of a metal such as titanium nitride (TiN), aluminum (Al), copper (Cu) and the like is included in the dicing region, SF₆ employed for etching silicon cannot provide an etching of these metals. Consequently, it is necessary to employ a reactive ion etching (RIE) using chlorine (Cl) for an Al film. Further, it is necessary to employ an ion beam milling process instead of RIE, for TiN and Cu.

On the other hand, in the process described in Japanese Patent Laid-Open No. 2004-55,684, a metal layer is provided on a back surface of a wafer and an irradiation with a laser beam is conducted, and a side of the device-forming surface is diced by an etch process. Consequently, the manufacturing process operation for stripping the interconnect layer could be complicated, similarly as in the case of Japanese Patent Laid-Open No. 2003-179,005.

On the contrary, since the semiconductor device 100 of the present invention can be obtained by the removing operation via the irradiation with the laser beam, in place of the removing operation for the interconnect layer 103 via the etching, the process is configured to allow a stable and simple manufacturing process for the devices.

Further, the semiconductor device 100 is also configured that the partially removing process for the whole thickness of the interconnect layer 103 and the partial thickness of the silicon wafer 101 from the side of the device-forming surface are conducted via a laser beam, and another partially removing process for the rest of the thickness of the silicon wafer 101 is conducted via a dry etch process. Consequently, the device is configured to have an improved manufacturing stability for the removing operation and to be capable of inhibiting an increase of the manufacturing cost. Since the silicon wafer 101, which has not been etched for reducing the thickness, has a thickness of, for example, about 500 to 800 μm, as described above, it is difficult to proceed the removal over the entire thickness thereof via an irradiation with a laser beam employing, for example, YAG laser. Although the silicon wafer 101 can be partially removed along the whole thickness thereof via an irradiation with a laser beam by employing, for example, an excimer laser, the irradiation with the laser beam generally requires longer removal time for removing along the depth direction as compared with the etching process though the irradiation with the laser beam allows to reduce the width of the removed region, and therefore the manufacturing cost is increased.

Consequently, in the present embodiment, an irradiation with a laser beam is conducted to partially remove the silicon wafer 101 in the depth direction to a halfway of the entire thickness thereof, and then, a dry etch process is conducted to further remove the rest of the thickness of the silicon wafer 101 in depth direction. Since the dry etch process effectively removes the silicon even if the opening width is about 1 μm, a combined use of the dry etch process and the irradiation with the laser beam reduces the required dicing width and reduces a time required for the dicing process, so that an increase of a manufacturing cost can be inhibited, while increasing degree of integration of the semiconductor devices 100 in the device-forming region on the silicon wafer 101.

The semiconductor device 100 is further partially removed by a back surface-polishing operation, after the etch process for the silicon wafer 101. Then, the adhesive tape 109 is stripped at the outside of the vacuum chamber employed for the etch process to eventually complete the dividing operation. Thus, the semiconductor device 100 is configured to be obtainable by the manufacturing process that exhibits an improved handling for the dividing operation, as compared with the case of the second embodiment as discussed later. Further, the process can be configured to allow manufacturing the semiconductor device 100 in further shorter time than the case of the second embodiment.

In addition to above, when the combination of the irradiation with the laser beam from the side of the device-forming surface and the dry etch process is employed, contaminants generated by partially removing the interconnect layer 103 and the silicon wafer 101 during the removing process via the irradiation with the laser beam are emitted to the outside of the trenched portion 107 and the emitted contaminants are adhered to the surface of the interconnect layer 103 or the like, resulting in a problem of deteriorations of the insulating film and/or the interconnect. Consequently, in the present embodiment, the interconnect layer 103 is coated with the protective film 105 in advance, and then, the irradiation with the laser beam is conducted. Having such configuration, the contaminants generated in the irradiation with the laser beam process can be adhered onto the protective film 105, thereby preventing from the contamination of interconnect layer 103. The contaminant adhered on the protective film 105 can also be removed together with the protective film 105 in the process for stripping the protective film 105.

When the irradiation with the laser beam is employed, contaminants generated in the irradiation with the laser beam are adhered onto the protective film 105, as described above. When only a dry process such as plasma ashing and the like is employed in the operation for stripping the protective film 105, there is a concern that the contaminants adhered on the protective film 105 could be adhered to the trenched portion 107, or could plug the trenched portion 107. Since the semiconductor device 100 is to be contaminated from the dicing surface 111 in this case, there is a concern for damaging the interconnect in the interconnect layer 103, for example.

Consequently, when the semiconductor device 100 is manufactured in the present embodiment, it is more preferable to employ a wet process, which involves cleaning the device-forming surface of the silicon wafer 101 with water or a predetermined organic solvent, in the stripping operation of protective film 105. By employing the wet process for the operation for stripping the protective film 105, the protective film 105 can be surely cleaned and the contaminants adhered to the protective film 105 can also be surely removed from the trenched portion 107 and the interconnect layer 103.

Since the process disclosed in Japanese Patent Laid-Open No. 2004-55,684 described in the section of the background of the invention involves providing the metal layer on the back surface of the wafer and conducting the irradiation with the laser beam from the upper direction thereof, an use of an etchant solution containing, for example, acid and alkali may be required for removing the metal film. In such occasion, metallic ion is to contact with silicon that exists in a bare status in an etching trench to cause a contamination of the wafer. In particular, it is known that copper ion diffuses in silicon and the diffused copper ion modifies characteristics of transistor, so that, when the metal film contains copper, there is a concern of causing a remarkable problem of a wafer contamination generated by stripping the metal film. Further, when a back surface electrode containing a metal such as aluminum (Al) or copper (Cu) is provided on the back surface of the wafer, there is a concern for the back surface electrode to be corroded by an exposure of the back surface electrode to an etchant solution in the process for stripping the metal film.

In recent years, there is a tendency that the semiconductor chip is miniaturized, and in order to miniaturize the semiconductor chip, it is necessary to dispose the dicing region at a location closer to the transistor. From this point of view, there is a concern that a contamination may be generated by metallic ion in the process disclosed in Japanese Patent Laid-Open No. 2004-55,684, and therefore it is difficult to dispose the transistor at a location closer to the dicing region. As such, according to the process disclosed in Japanese Patent Laid-Open No. 2004-55,684, the available configuration of the semiconductor chip is limited, and thus there is a room for improving a degree of flexibility of configurations of a front surface and a back surface of a semiconductor wafer.

Therefore, in the present embodiment, a nonmetallic material is employed for the material of the protective film 105, so that a generation of such contamination can be inhibited. This can provide further improved production yield of the semiconductor device 100.

Further, in the present embodiment, it is more preferable to manufacture the semiconductor device 100 by a process that does not include an operation for stripping the metal film on the device-forming surface, after the formation of the trenched portion 107. This can provide more surely inhibition to a generation of a contamination to the silicon wafer 101. Further, a degree of integration in the device-forming region provided on the silicon wafer 101 can be enhanced.

In addition, the operation for stripping the protective film 105 can exclusively include a wet process by employing a water-soluble material or an organic solvent-soluble material for the protective film 105, and therefore, the semiconductor device 100 can be configured to be manufactured in a simple and easy way. In addition, since the semiconductor device 100 can be configured to have further improved production yield, the semiconductor device 100 can be configured to have further improved mass productivity. In addition, when a sublimable material is employed for the material of the protective film 105, it is preferable to conduct a cleaning via a wet process after silicon wafer 101 is heated to strip the protective film 105.

In the following embodiments, descriptions will be made by focusing points that are different from first embodiment.

### Second Embodiment

In first embodiment, after the dry etching operation in step 103 (FIG. 1C), the protective film 105 is stripped (FIG. 2A), and the back surface grinding is conducted for the silicon wafer 101 to obtain a plurality of semiconductor devices 100 (FIG. 2B). In the present embodiment, the dry etch process for the silicon wafer 101 is further continued, in place of the back surface polishing, to divide the silicon wafer 101 into a plurality of semiconductor devices 100. More specifically, the operation for dividing the silicon wafer 101 into pieces in step 104 includes an operation for further removing the silicon wafer 101 in depth direction from the bottom of the trenched portion 107 via an etch process. The operation for removing the protective film 105 in step 106 is conducted after the after the operation for dividing the wafer in step 104.

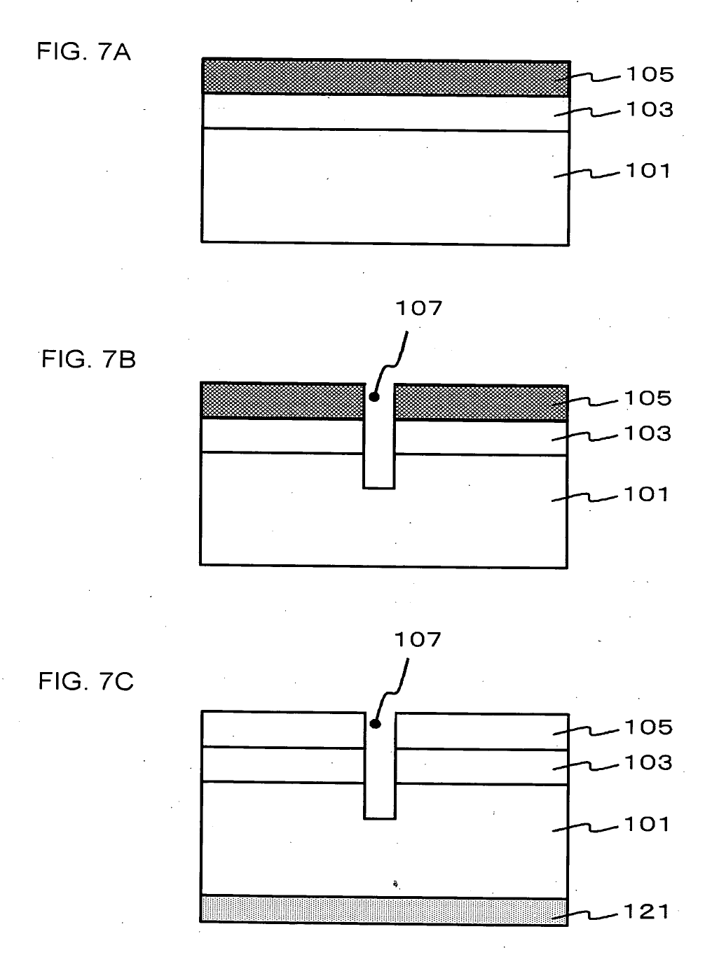

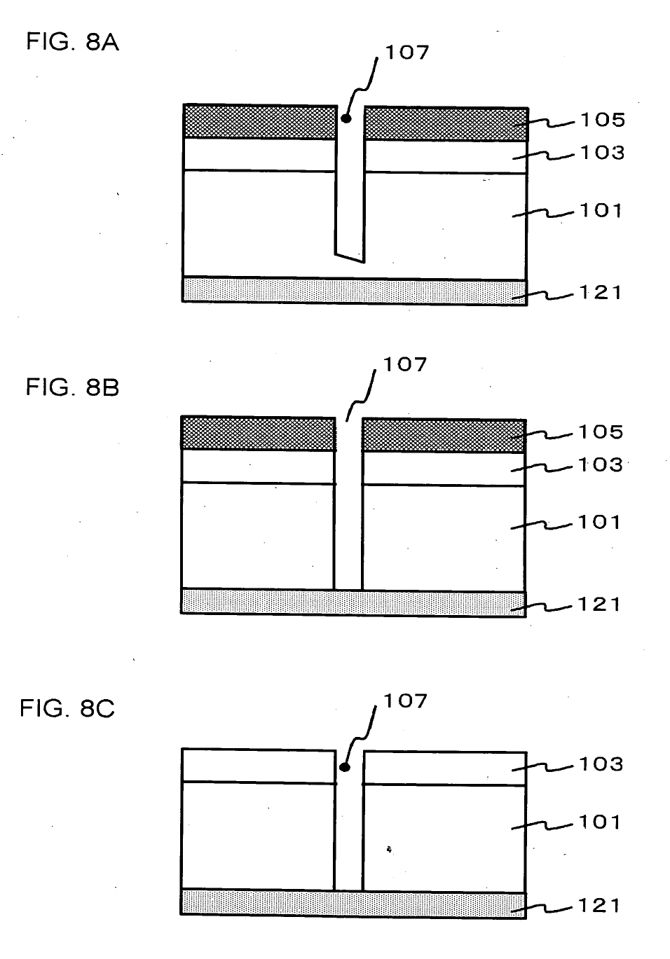

FIG. 7A to FIG. 7C and FIG. 8A to FIG. 8C are cross-sectional views, illustrating a process for manufacturing a semiconductor device in the present embodiment. First of all, similarly as in first embodiment, an LSI including a certain device, a certain diffusion layer and a certain interconnect layer 103 is formed on a device-forming surface of the silicon wafer 101 (FIG. 3). Then, the protective film 105 is provided over the entire surface of the device-forming surface of the silicon wafer 101 having the LSIs formed thereon (FIG. 7A), and then, an irradiation with a laser beam is conducted along dicing lines 120 (FIG. 3) to form the trenched portion 107, which extends through the protective film 105 and the interconnect layer 103, and reaches to the inside of the silicon wafer 101 (FIG. 7B).

Next, an adhesive tape 121 is adhered onto a back surface of the silicon wafer 101 (FIG. 7C). For example, a known dicing tape may be employed for the adhesive tape 121. Then, the removal of the portion of the silicon wafer 101 is further proceeded toward the depth direction from the bottom of the trenched portion 107 (FIG. 8A). Thereafter, in the present embodiment, the protective film 105 is not removed, and the dry etch process for the trenched portion 107 of the silicon wafer 101 is further proceeded toward the depth direction until the trenched portion 107 eventually extends through the back surface thereof (FIG. 8B). Then, the protective film 105 is stripped by employing the method described in first embodiment (FIG. 8C). Thereafter, the adhesive tape 121 is stripped from the back surface of the silicon wafer 101 to provide divided pieces of the silicon wafer 101, thereby obtaining a plurality of semiconductor devices 100.

According to the present embodiment, after completing step 103, the dry etch process is further conducted in step 104 to obtain the semiconductor device. Consequently, the operation for dividing the semiconductor device into pieces can be conducted within the vacuum chamber that is employed for the etch process, so that the process for manufacturing the semiconductor device can be simplified. In addition, in the pieces of the semiconductor device 100 obtained by dividing operation, the thickness of the silicon wafer 101 can be fully assured.

While the descriptions have been made in the above-described embodiments by illustrating the cases of conducting the dicing process for the silicon wafer 101 after forming the circuit of LSI, the timing for conducting the dicing process is not limited to the stage after forming the circuit of LSI, and various timing may be employed. Other exemplary implementations for the dicing process will be described as follows.

### Third Embodiment

In the present embodiment, a pad electrode and a metal-plated bump are further provided on the interconnect layer 103, and thereafter, a dicing process is conducted. In this case, a plurality of semiconductor devices can similarly be obtained from one piece of the silicon wafer 101 by employing the process described in the above embodiments.

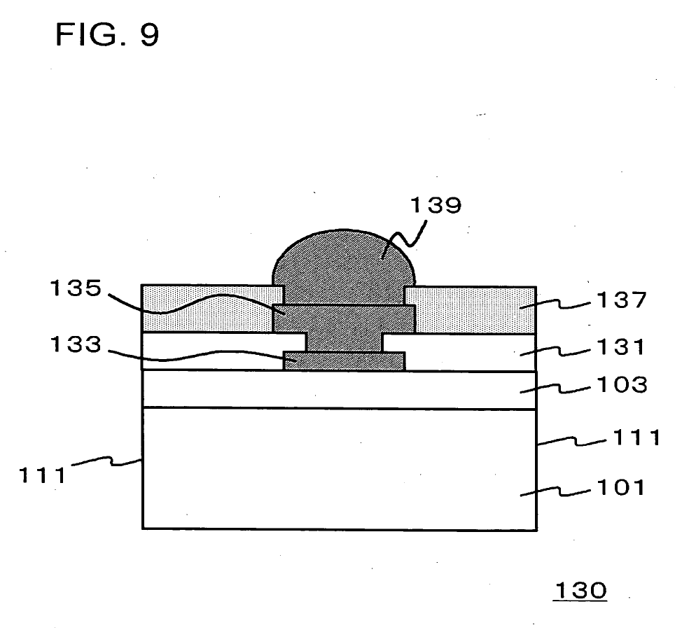

FIG. 9 is a cross-sectional view, illustrating a configuration of a semiconductor device of the present embodiment. A semiconductor device 130 shown in FIG. 9 further includes the following members, in addition to the configuration of the semiconductor device 100 shown in FIG. 1. More specifically, an insulating interlayer 131 is provided on an interconnect layer 103, and an interconnect 133 is buried within the insulating interlayer 131. Materials of the interconnect 133 may include, for example, conductive materials such as metals such as Cu or Al and the like. In addition, an electroconductive electrode pad 135 is provided on the interconnect 133, so that the electrode pad 135 is in contact with the interconnect 133. Side surfaces and portions of the upper surface of the electrode pad 135 is covered with a passivation film 137. The passivation film 137 may be composed of, for example, a polyimide film. A portion of the upper surface of the electrode pad 135 is not covered with the passivation film 137, and a bump 139 is provided so as to be in contact with the uncovered portion of the electrode pad 135. The bump 139 may be composed of, for example, a solder ball.

Next, a method for manufacturing the semiconductor device 130 will be described by illustrating a method employing the manufacturing process described in first embodiment. The method for manufacturing the semiconductor device according to the present embodiment includes providing the electrode pad 135 connected to the interconnect in the interconnect layer 103 and the electroconductive bump 139 connected to the electrode pad 135, after providing the interconnect layer 103 (step 105) and before providing a protective film 105 (step 101). The electrode pad 135 is provided in a device-forming region of the silicon wafer 101.

More specifically, first of all, the interconnect layer 103, the insulating interlayer 131, the interconnect 133, the electrode pad 135, the passivation film 137 and the bump 139 are formed on the silicon wafer 101 by employing a known method. Then, the protective film 105 is provided on a device-forming surface of silicon wafer 101, on which the bump 139 is formed by the above-described formation process. In this case, in the region for forming the bump 139, the protective film 105 may cover the upper surface of bump 139, or may not cover thereof. Thereafter, the silicon wafer 101 is divided into pieces according to the procedure described above in reference to FIG. 1C, FIG. 2A and FIG. 2B to obtain a plurality of semiconductor devices 130.

The dicing process is also conducted in the present embodiment, by combining the irradiation with the laser beam process, the dry etch process and the back surface polishing process, after forming the protective film 105. Consequently, similar advantageous effects obtainable by employing the above-described embodiments can also be obtained, even in the case, in which the electrode pad 135 and the bump 139 are formed on silicon wafer 101 in advance.

Alternatively, the dividing operation in step 103 may be conducted by the dry etch process described in second embodiment.

### Fourth Embodiment

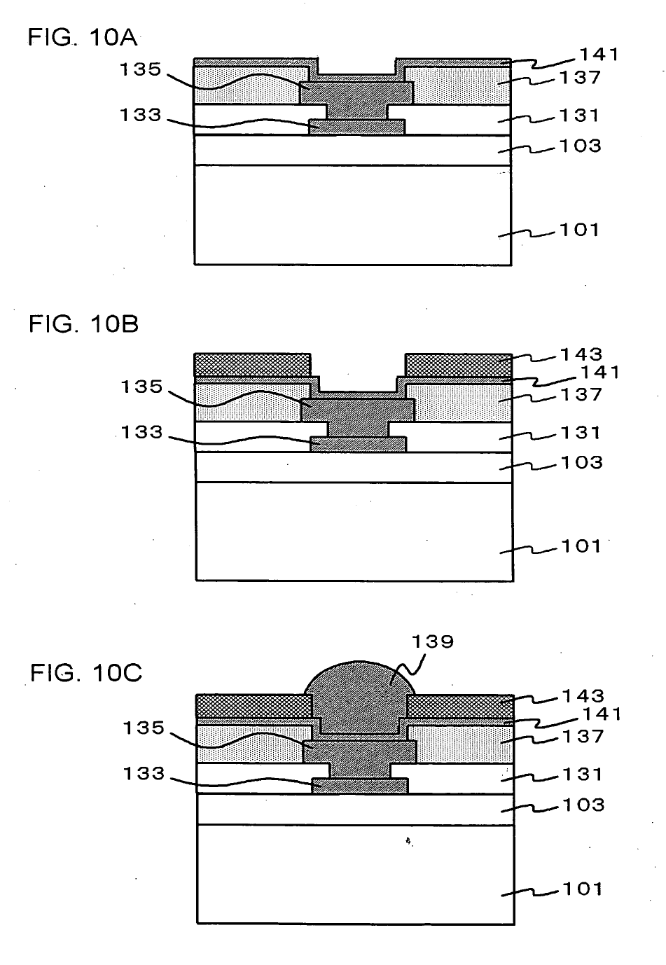

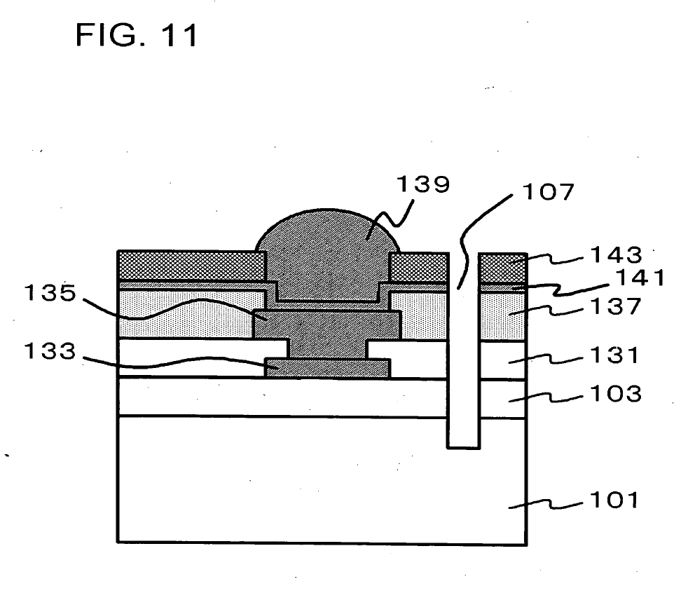

In the semiconductor device 130 shown in FIG. 9, a seed layer (seed layer 141 of FIG. 10A to FIG. 10C and FIG. 11) for growing the bump 139 via an electroplating may be provided on the electrode pad 135. When the semiconductor device 130 including the seed layer 141 is manufactured, a plating resist for the use in the operation for forming bump 139 may be employed as a protective film 105.

The method for manufacturing the semiconductor device of the present embodiment further includes providing an electrode pad 135 that is connected to an interconnect in an interconnect layer 103 and a metal layer (seed layer 141) that is connected to the electrode pad 135, after providing the interconnect layer 103 and before providing the protective film 105 (step 101). The operation for providing the protective film 105 includes forming the protective film 105 on the seed layer 141 so that the protective film 105 has an opening that is located above the electrode pad 135. The method further includes growing a metal film from the seed layer 141 exposed in the opening as a basic point, so as to fill the interior of the opening, after providing the protective film 105 (step 101) and before stripping the protective film 105. The operation for growing the metal film corresponds to, for example, an operation for growing the bump 139 via a metal plating process by utilizing the seed layer 141 as a seed layer for the growth. Alternatively, in place of the process for growing seed layer 141 so as to fill the interior of the opening, a solder bump 139 may be formed by providing solder ball or the like in the opening.

The process for manufacturing the semiconductor device 130 according to the present embodiment will be described in detail as follows. FIG. 10A to FIG. 10C and FIG. 11, are cross-sectional views of the semiconductor device, illustrating the process for manufacturing of the semiconductor device 130 of the present embodiment. First of all, as shown in FIG. 10A, the interconnect layer 103, an insulating interlayer 131, an interconnect 133, the electrode pad 135 and a passivation film 137 are formed on a device-forming surface of the silicon wafer 101. Then, the seed layer 141 for growing the bump 139 via an electrical plating process is formed on the entire upper surface of the silicon wafer 101 having the passivation film 137 provided thereon (FIG. 10A).

Subsequently, a plating resist 143 having an opening above the electrode pad 135 is provided in a predetermined region on the seed layer 141 (FIG. 10B). The plating resist 143 functions as a protective film in the process for forming the trenched portion 107 as discussed later. The available materials for the plating resist 143 may be typically, for example, the materials exemplified as the available materials for the protective film 105 in first embodiment.

Then, a metal film is grown from the exposed region of the seed layer 141 to form the bump 139 (FIG. 10C). Thereafter, the plating resist 143 is not stripped, and rather is employed as a protective film, and then, an irradiation with a laser beam is conducted along a dicing line (not shown) to form a trenched portion 107 that extends from the plating resist 143 to the inside of the silicon wafer 101 (FIG. 11). Thereafter, etching of the trenched portion 107 is further proceeded in the depth direction employing the procedure described above in reference to FIG. 1C and FIG. 2A in first embodiment to remove the plating resist 143. Thereafter, the seed layer 141 is stripped via the etch process. Then, as described above in reference to FIG. 2B, a back surface polishing of the silicon wafer 101 is conducted to obtain the semiconductor device 130.

Since the plating resist 143 can be employed for the protective film in the dicing process according to the present embodiment, number of the process steps for the deposition process can be reduced. In addition to above, since the process of the present embodiment includes the operation for removing the seed layer 141 after stripping the plating resist 143 that functions as the protective film, it is preferable to provide a dicing region, which has an allowance in a circumference of the device-forming region of the silicon wafer 101, which has a suitable dimension to avoid contaminating the interconnect layer 103 and the silicon wafer 101 with contaminants generated from the inner surface of the trenched portion 107 in the seed layer 141.

Alternatively, the dividing operation in step 103 may be conducted by the dry etch process described in second embodiment.

While the preferred embodiments of the present invention have been described above in reference to the annexed figures, it should be understood that the disclosures above are presented for the purpose of illustrating the present invention only, and various configurations other than the above described configurations can also be adopted.

It is apparent that the present invention is not limited to the above embodiment, that may be modified and changed without departing from the scope and spirit of the invention.

What is claimed is:

1. A method for manufacturing a semiconductor device, comprising:
providing an interconnect layer on a device-forming surface of a semiconductor substrate;
providing a protective film on said interconnect layer;
irradiating said protective film with a laser beam to provide a trenched portion that extends from said protective film through said interconnect layer and reaches to an inside of said semiconductor substrate;
removing a portion of said semiconductor substrate selectively in depth direction from a bottom of said trenched portion, after said irradiating with the laser beam to provide the trenched portion; and
dividing said semiconductor substrate along the portion where said trenched portion is provided into respective pieces of said semiconductor substrate, after said removing the portion of the semiconductor substrate selectively in depth direction.

2. The method according to claim 1,
wherein said removing the portion of semiconductor substrate selectively in depth direction includes removing said semiconductor substrate via an etch process.

3. The method according to claim 1,
wherein said dividing said semiconductor substrate into respective pieces includes reducing thickness of said semiconductor substrate from a back surface of said semiconductor substrate.

4. The method according to claim 1,
wherein said dividing said semiconductor substrate into respective pieces includes further removing said semiconductor substrate in depth direction from a bottom of said trenched portion via an etch process.

5. The method according to claim 1,
wherein said providing the interconnect layer includes providing an interconnect in said interconnect layer in a region, which is irradiated with said laser beam, and
said providing the trenched portion includes providing said trenched portion that extends from said protective film through said interconnect layer to an inside of said semiconductor substrate, and breaking said interconnect.

6. The method according to claim 1,
wherein said method further comprises providing an electrode pad connected to the interconnect in said interconnect layer and an electroconductive bump connected to said electrode pad, after said providing the interconnect layer and before said providing the protective film.

7. The method according to claim 1,
wherein said method further comprises providing an electrode pad connected to the interconnect in said interconnect layer and a metal layer connected to said electrode pad, after said providing the interconnect layer and before said providing the protective film,
wherein said providing the protective film includes forming the protective film on said metal layer, said protective film having an opening that is located above said electrode pad, and
wherein said method further comprises growing a metal film from an exposed portion of said metal layer exposed in said opening as a basic point, so as to fill the interior of said opening, after said providing the protective film and before said providing the trenched portion.

8. The method according to claim 1,
wherein said method further comprises removing said protective film, after said removing a portion of said semiconductor substrate selectively in depth direction.

9. The method according to claim 8,
wherein said protective film is a film containing a water-soluble resin, and
said removing said protective film comprises removing said protective film by cleaning said device-forming surface with water.

10. The method according to claim 8,
wherein said protective film is a film that contains an organic solvent-soluble resin, and
said removing said protective film comprises removing said protective film by cleaning said device-forming surface with an organic solvent.

11. The method according to claim 1, wherein said protective film is composed of a nonmetallic material.
